(19) United States
(12) Patent Application Publication
(10) Pub. No.: US 2025/0088167 A1
(43) Pub. Date: Mar. 13, 2025

(54) TRANSVERSELY-EXCITED FILM BULK ACOUSTIC RESONATOR WITH A CAVITY HAVING ROUND END ZONES

(71) Applicant: Murata Manufacturing Co., Ltd., Nagaokakyo-shi (JP)

(72) Inventors: Kuan ZHANG, Goleta, CA (US); James R. COSTA, Lompoc, CA (US); Andrew KAY, Provo, UT (US); Greg DYER, Santa Barbara, CA (US); Viktor PLESSKI, Gorgier (CH); Soumya YANDRAPALLI, Amsterdam (NL); Robert B. HAMMOND, Santa Barbara, CA (US); Bryant GARCIA, Mississauga (CA); Patrick TURNER, Portola Valley, CA (US); Jesson JOHN, Dublin, CA (US); Ventsislav YANTCHEV, Sofia (BG)

(21) Appl. No.: 18/960,226

(22) Filed: Nov. 26, 2024

Related U.S. Application Data
(63) Continuation of application No. 17/330,219, filed on May 25, 2021, now Pat. No. 12,184,261.
Application No. 17/330,219 is a continuation-in-part of application No. 17/030,029, filed on Sep. 23, 2020, now Pat. No. 11,228,296.
Application No. 17/030,029 is a continuation-in-part of application No. 16/920,173, filed on Jul. 2, 2020, now Pat. No. 11,139,794.
Application No. 16/920,173 is a continuation of application No. 16/438,121, filed on Jun. 11, 2019, now Pat. No. 10,756,697.
Application No. 16/438,121 is a continuation-in-part of application No. 16/230,443, filed on Dec. 21, 2018, now Pat. No. 10,491,192.
(60) Provisional application No. 62/904,126, filed on Sep. 23, 2019.
(60) Provisional application No. 62/753,815, filed on Oct. 31, 2018.
(60) Provisional application No. 62/748,883, filed on Oct. 22, 2018.
(60) Provisional application No. 62/741,702, filed on Oct. 5, 2018.
(60) Provisional application No. 62/701,363, filed on Jul. 20, 2018.
(60) Provisional application No. 62/685,825, filed on Jun. 15, 2018.

(51) Int. Cl. H03H 9/02; H03H 3/02; H03H 3/04; H03H 9/13; H03H 9/17; H03H 9/56

(52) U.S. Cl. CPC H03H 9/02228; H03H 3/04; H03H 9/02031; H03H 9/132; H03H 9/174; H03H 9/176; H03H 9/562; H03H 9/564; H03H 9/568; H03H 2003/023; H03H 2003/0442

(57) ABSTRACT

Acoustic filters, resonators and methods are disclosed. An acoustic filter device includes a substrate; a piezoelectric layer attached to the substrate, wherein at least a portion of the piezoelectric layer is disposed over a cavity of the acoustic resonator device; and an interdigital transducer (IDT) on a surface of the piezoelectric layer, the IDT including interleaved fingers extending at least over the portion of the piezoelectric layer disposed over the cavity. The cavity has at least one rounded corner, and a portion of interleaved fingers extend from at least one busbar. Moreover, at least a portion of the rounded corner of the cavity is under the at least one busbar in a plan view of the piezoelectric layer.

### CROSS REFERENCE TO RELATED APPLICATIONS

This patent application is a continuation of U.S. patent application Ser. No. 17/330,219, filed May 25, 2021, which is a continuation-in-part of U.S. patent application Ser. No. 17/030,029, filed Sep. 23, 2020, now issued as U.S. Pat. No. 11,228,296, which claims priority to U.S. Provisional Application No. 62/904,126, filed Sep. 23, 2019, entitled “CURVED XBAR RESONATOR GEOMETRIES TO ENGINEER RESIDUAL STRESSES” and is also a continuation-in-part of U.S. patent application Ser. No. 16/920,173, filed Jul. 2, 2020, now issued as U.S. Pat. No. 11,139,794, which is a continuation of U.S. patent application Ser. No. 16/438,121, filed Jun. 11, 2019, now issued as U.S. Pat. No. 10,756,697, which is a continuation-in-part of U.S. patent application Ser. No. 16/230,443, filed Dec. 21, 2018, now issued as U.S. Pat. No. 10,491,192 B2, which claims priority from the following provisional patent applications: U.S. Provisional Application No. 62/685,825, filed Jun. 15, 2018, entitled “SHEAR-MODE FBAR (XBAR)”; U.S. Provisional Application No. 62/701,363, filed Jul. 20, 2018, entitled “SHEAR-MODE FBAR (XBAR)”; U.S. Provisional Application No. 62/741,702, filed Oct. 5, 2018, entitled “5 GHz LATERALLY-EXCITED BULK WAVE RESONATOR (XBAR)”; U.S. Provisional Application No. 62/748,883, filed Oct. 22, 2018, entitled “SHEAR-MODE FILM BULK ACOUSTIC RESONATOR”; and U.S. Provisional Application No. 62/753,815, filed Oct. 31, 2018, entitled “LITHIUM TANTALATE SHEAR-MODE FILM BULK ACOUSTIC RESONATOR”. All of these applications are incorporated herein by reference in their entireties.

### TECHNICAL FIELD

This disclosure relates to radio frequency filters using acoustic wave resonators, and specifically to filters for use in communications equipment.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “pass-band” of the filter. The range of frequencies stopped by such a filter is referred to as the “stop-band” of the filter. A typical RF filter has at least one pass-band and at least one stop-band. Specific requirements on a passband or stop-band depend on the specific application. For example, a “pass-band” may be defined as a frequency range where the insertion loss of a filter is better than a defined value such as 1 dB, 2 dB, or 3 dB. A “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front-ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

RF filters typically require many design trade-offs to achieve, for each specific application, the best compromise between performance parameters such as insertion loss, rejection, isolation, power handling, linearity, size and cost. Specific design and manufacturing methods and enhancements can benefit simultaneously one or several of these requirements.

Performance enhancements to the RF filters in a wireless system can have broad impact to system performance. Improvements in RF filters can be leveraged to provide system performance improvements such as larger cell size, longer battery life, higher data rates, greater network capacity, lower cost, enhanced security, higher reliability, etc. These improvements can be realized at many levels of the wireless system both separately and in combination, for example at the RF module, RF transceiver, mobile or fixed sub-system, or network levels.

The desire for wider communication channel bandwidths will inevitably lead to the use of higher frequency communications bands. The current LTE™ (Long Term Evolution) specification defines frequency bands from 3.3 GHz to 5.9 GHz. These bands are not presently used. Future proposals for wireless communications include millimeter wave communication bands with frequencies up to 28 GHz.

High performance RF filters for present communication systems commonly incorporate acoustic wave resonators including surface acoustic wave (SAW) resonators, bulk acoustic wave (BAW) resonators, film bulk acoustic wave resonators (FBAR), and other types of acoustic resonators. However, these existing technologies are not well-suited for use at the higher frequencies proposed for future communications networks.

### BRIEF DESCRIPTION OF THE DRAWINGS

FIG. 1 has a schematic plan view and two schematic cross-sectional views of a transversely-excited film bulk acoustic resonator (XBAR).

FIG. 2 is an expanded schematic cross-sectional view of a portion of the XBAR of FIG. 1.

FIG. 3 is an alternative schematic cross-sectional view of the XBAR of FIG. 1.

FIG. 4 is a graphic illustrating a shear primary acoustic mode in an XBAR.

FIG. 5 is a schematic block diagram of a filter using XBARs.

FIG. 6 is a schematic cross-sectional view of two XBARs illustrating a frequency-setting dielectric layer.

FIG. 7 is a graphic illustrating the definition of the curvature of a line.

FIG. 8 is schematic plan view of an XBAR with a cavity having a curved perimeter.

FIG. 9A is schematic plan view of another XBAR with a cavity having a curved perimeter.

FIG. 9B is schematic plan view of another XBAR with a cavity having round end zones.

FIG. 10 is schematic plan view of another XBAR with a cavity having a curved perimeter.

FIG. 11 is schematic plan view of another XBAR with a cavity having an elliptical perimeter.

FIG. 12 is a flow chart of a process for fabricating an XBAR or filter incorporation XBARs.

Throughout this description, elements appearing in figures are assigned three-digit or four-digit reference designators, where the two least significant digits are specific to the element and the one or two most significant digit is the figure number where the element is first introduced. An element that is not described in conjunction with a figure may be presumed to have the same characteristics and function as a previously-described element having the same reference designator.

### DETAILED DESCRIPTION

### Description of Apparatus

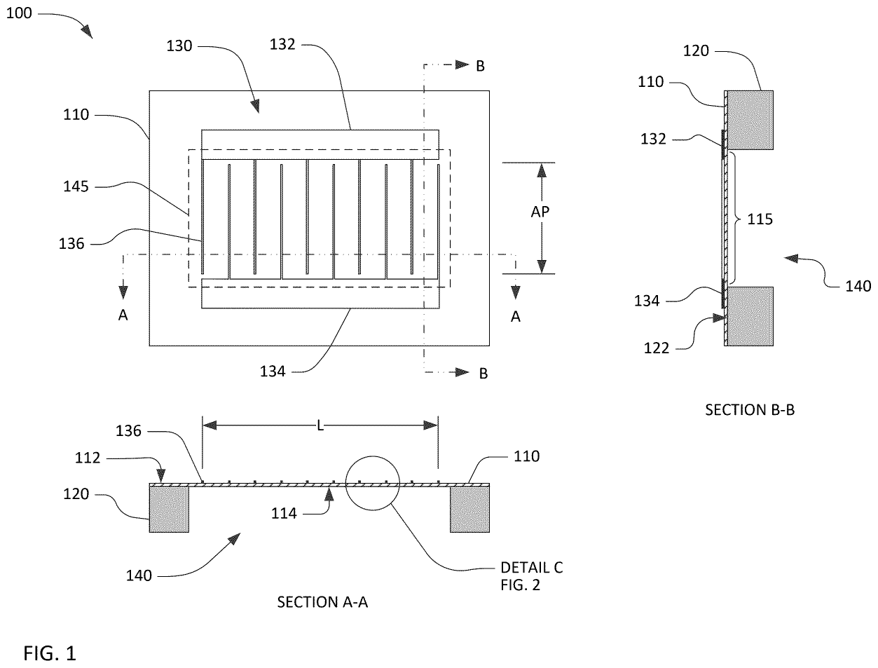

FIG. 1 shows a simplified schematic top view and orthogonal cross-sectional views of a transversely-excited film bulk acoustic resonator (XBAR) 100. XBAR resonators such as the resonator 100 may be used in a variety of RF filters including band-reject filters, band-pass filters, duplexers, and multiplexers. XBARs are well suited for use in filters for communications bands with frequencies above 3 GHz.

The XBAR 100 is made up of a thin film conductor pattern formed on a surface of a piezoelectric plate 110 having a front surface 112 and a back surface 114. The front and back surfaces are essentially parallel. “Essentially parallel” means parallel to the extent possible within normal manufacturing tolerances. The piezoelectric plate is a thin single-crystal layer of a piezoelectric material such as lithium niobate, lithium tantalate, lanthanum gallium silicate, gallium nitride, or aluminum nitride. The piezoelectric plate is cut such that the orientation of the X, Y, and Z crystalline axes with respect to the front and back surfaces is known and consistent. In the examples presented in this patent, the piezoelectric plates are Z-cut, which is to say the Z axis is normal to the front surface 112 and back surface 114. However, XBARs may be fabricated on piezoelectric plates with other crystallographic orientations including rotated Z-cut and rotated YX-cut.

The back surface 114 of the piezoelectric plate 110 is attached to a surface 122 of the substrate 120 except for a portion of the piezoelectric plate 110 that forms a diaphragm 115 spanning a cavity 140 formed in the substrate 120. The cavity 140 has a perimeter defined by the intersection of the cavity and the surface 122 of the substrate 120. The portion of the piezoelectric plate that spans the cavity is referred to herein as the “diaphragm” due to its physical resemblance to the diaphragm of a microphone. As shown in FIG. 1, the diaphragm 115 is contiguous with the rest of the piezoelectric plate 110 around all of the perimeter 145 of the cavity 140. In this context, “contiguous” means “continuously connected without any intervening item”.

The substrate 120 provides mechanical support to the piezoelectric plate 110. The substrate 120 may be, for example, silicon, sapphire, quartz, or some other material or combination of materials. The back surface 114 of the piezoelectric plate 110 may be attached to the substrate 120 using a wafer bonding process. Alternatively, the piezoelectric plate 110 may be grown on the substrate 120 or otherwise attached to the substrate. The piezoelectric plate 110 may be attached directly to the substrate or may be attached to the substrate 120 via one or more intermediate material layers.

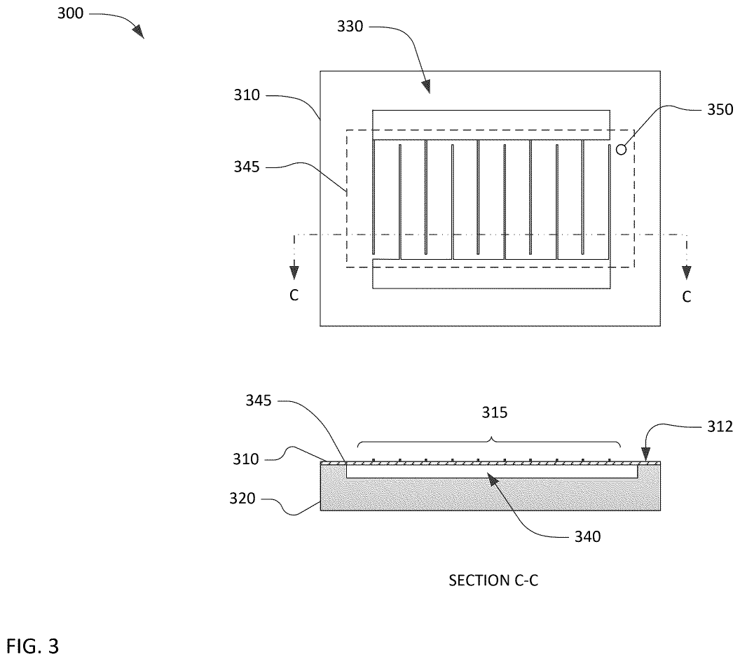

The cavity 140 is an empty space within a solid body of the resonator 100. The cavity 140 may be a hole completely through the substrate 120 (as shown in Section A-A and Section B-B) or a recess in the substrate 120 (as shown subsequently in FIG. 3). The cavity 140 may be formed, for example, by selective etching of the substrate 120 before or after the piezoelectric plate 110 and the substrate 120 are attached.

The conductor pattern of the XBAR 100 includes an interdigital transducer (IDT) 130. An IDT is an electrode structure for converting between electrical and acoustic energy in piezoelectric devices. The IDT 130 includes a first plurality of parallel elongated conductors, commonly called “fingers”, such as finger 136, extending from a first busbar 132. The IDT 130 includes a second plurality of fingers extending from a second busbar 134. The first and second pluralities of parallel fingers are interleaved. The interleaved fingers overlap for a distance AP, commonly referred to as the “aperture” of the IDT. The center-to-center distance L between the outermost fingers of the IDT 130 is the “length” of the IDT.

The term “busbar” refers to the conductors that interconnect the first and second sets of fingers in an IDT. As shown in FIG. 1, each busbar 132, 134 is an elongated rectangular conductor with a long axis orthogonal to the interleaved fingers and having a length approximately equal to the length L of the IDT. The busbars of an IDT need not be rectangular or orthogonal to the interleaved fingers and may have lengths longer than the length of the IDT.

The first and second busbars 132, 134 serve as the terminals of the XBAR 100. A radio frequency or microwave signal applied between the two busbars 132, 134 of the IDT 130 excites a primary acoustic mode within the piezoelectric plate 110. As will be discussed in further detail, the primary acoustic mode is a bulk shear mode where acoustic energy propagates along a direction substantially orthogonal to the surface of the piezoelectric plate 110, which is also normal, or transverse, to the direction of the electric field created by the IDT fingers. Thus, the XBAR is considered a transversely-excited film bulk wave resonator.

The IDT 130 is positioned on the piezoelectric plate 110 such that at least the fingers of the IDT 130 are disposed on the diaphragm 115 of the piezoelectric plate that spans, or is suspended over, the cavity 140. As shown in FIG. 1, the cavity 140 has a rectangular shape with an extent greater than the aperture AP and length L of the IDT 130. A cavity of an XBAR may have a different shape, such as a regular or irregular polygon. The cavity of an XBAR may more or fewer than four sides, which may be straight or curved.

For ease of presentation in FIG. 1, the geometric pitch and width of the IDT fingers is greatly exaggerated with respect to the length (dimension L) and aperture (dimension AP) of the XBAR. An XBAR for a 5G device will have more than ten parallel fingers in the IDT 110. An XBAR may have hundreds, possibly thousands, of parallel fingers in the IDT 110. Similarly, the thickness of the fingers in the cross-sectional views is greatly exaggerated in the drawings.

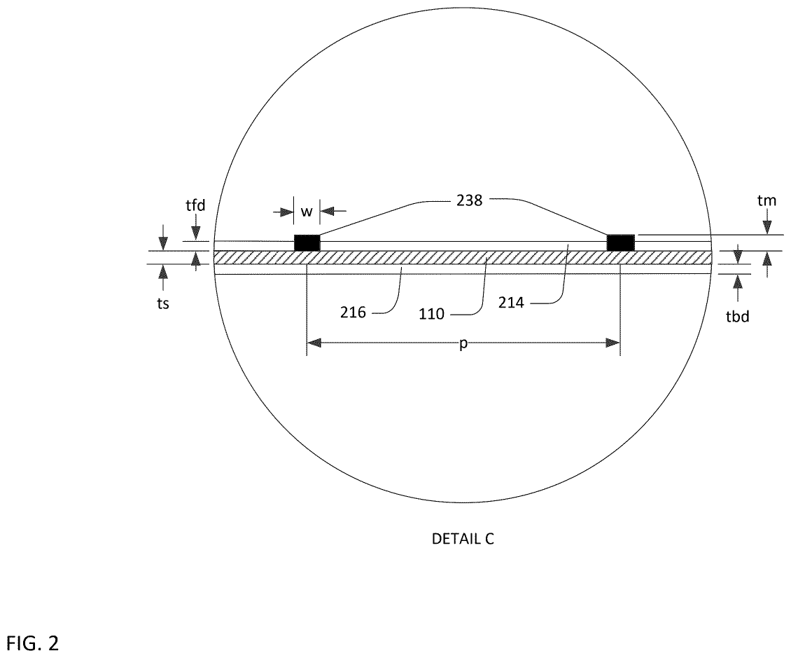

FIG. 2 shows a detailed schematic cross-sectional view of the XBAR 100. The piezoelectric plate 110 is a single-crystal layer of piezoelectrical material having a thickness ts. ts may be, for example, 100 nm to 1500 nm. When used in filters for LTE™ bands from 3.4 GHz to 6 GHz (e.g. bands 42, 43, 46), the thickness ts may be, for example, 200 nm to 1000 nm.

A front-side dielectric layer 214 may be formed on the front side of the piezoelectric plate 110. The “front side” of the XBAR is the surface facing away from the substrate. The front-side dielectric layer 214 has a thickness tfd. The front-side dielectric layer 214 is formed between the IDT fingers 238. Although not shown in FIG. 2, the front side dielectric layer 214 may also be deposited over the IDT fingers 238. A back-side dielectric layer 216 may be formed on the back side of the piezoelectric plate 110. The back-side dielectric layer 216 has a thickness tbd. The front-side and back-side dielectric layers 214, 216 may be a non-piezoelectric dielectric material, such as silicon dioxide or silicon nitride. tfd and tbd may be, for example, 0 to 500 nm. tfd and tbd are typically less than the thickness ts of the piezoelectric plate. tfd and tbd are not necessarily equal, and the front-side and back-side dielectric layers 214, 216 are not necessarily the same material. Either or both of the front-side and back-side dielectric layers 214, 216 may be formed of multiple layers of two or more materials.

The IDT fingers 238 may be one or more layers of aluminum, a substantially aluminum alloys, copper, a substantially copper alloys, beryllium, gold, molybdenum, or some other conductive material. Thin (relative to the total thickness of the conductors) layers of other metals, such as chromium or titanium, may be formed under and/or over the fingers to improve adhesion between the fingers and the piezoelectric plate 110 and/or to passivate or encapsulate the fingers. The busbars (132, 134 in FIG. 1) of the IDT may be made of the same or different materials as the fingers. As shown in FIG. 2, the IDT fingers 238 have rectangular cross-sections. The IDT fingers may have some other cross-sectional shape, such as trapezoidal.

Dimension p is the center-to-center spacing or “pitch” of the IDT fingers, which may be referred to as the pitch of the IDT and/or the pitch of the XBAR. Dimension w is the width or “mark” of the IDT fingers. The IDT of an XBAR differs substantially from the IDTs used in surface acoustic wave (SAW) resonators. In a SAW resonator, the pitch of the IDT is one-half of the acoustic wavelength at the resonance frequency. Additionally, the mark-to- pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers. In addition, the pitch p of the IDT is typically 2 to 20 times the thickness ts of the piezoelectric slab 212. The width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w. The thickness of the busbars (132, 134 in FIG. 1) of the IDT may be the same as, or greater than, the thickness tm of the IDT fingers.

FIG. 3 is a plan view and a cross-sectional view of another XBAR 300 which is similar to the XBAR 100 of FIG. 1. A piezoelectric plate 310 is attached to a substrate 320. A portion of the piezoelectric plate 310 forms a diaphragm 315 spanning a cavity 340 in the substrate 320. An IDT 330 is formed on the surface 312 of the piezoelectric plate as previously described.

Unlike the cavity 140 of FIG. 1, the cavity 340 does not fully penetrate the substrate 320. The cavity 340 may be formed, for example, by etching the substrate 320 before attaching the piezoelectric plate 310. Alternatively, the cavity 340 may be formed by etching the substrate 320 with a selective etchant that reaches the substrate through one or more openings, such as opening 350, provided in the piezoelectric plate 310. In this case, the diaphragm 315 may be contiguous with the rest of the piezoelectric plate 310 around a large portion of a perimeter 345 of the cavity 340. For example, the diaphragm 315 may be contiguous with the rest of the piezoelectric plate 310 around at least 50% of the perimeter 345 of the cavity 340.

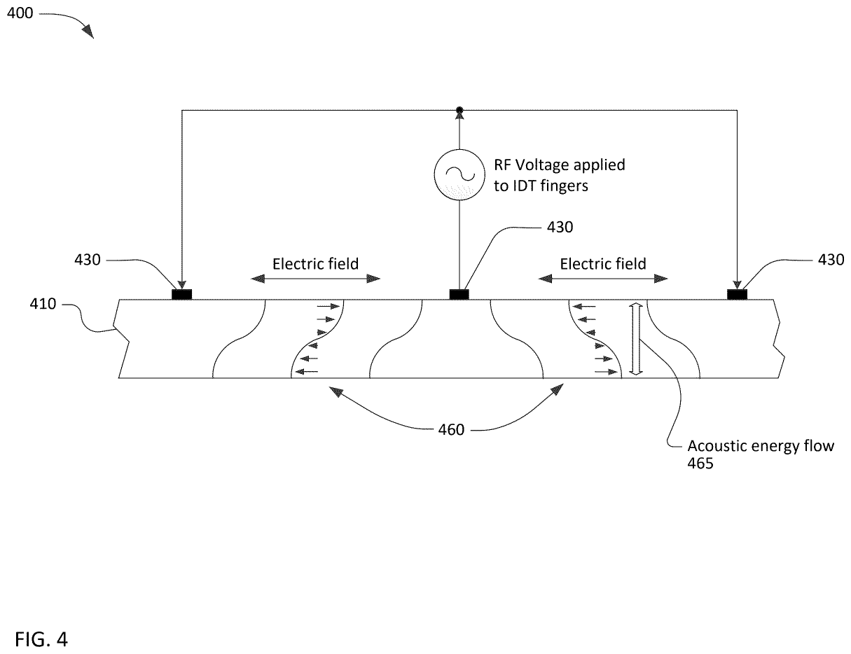

FIG. 4 is a graphical illustration of the primary acoustic mode of interest in an XBAR. FIG. 4 shows a small portion of an XBAR 400 including a piezoelectric plate 410 and three interleaved IDT fingers 430. A radio frequency (RF) voltage is applied to the interleaved fingers 430. This voltage creates a time-varying electric field between the fingers. The direction of the electric field is primarily lateral, or parallel to the surface of the piezoelectric plate 410, as indicated by the arrows labeled “electric field”. Since the dielectric constant of the piezoelectric plate is significantly higher than the surrounding air, the electric field is highly concentrated in the plate relative to the air. The lateral electric field introduces shear deformation, and thus strongly excites a shear-mode acoustic mode, in the piezoelectric plate 410. Shear deformation is deformation in which parallel planes in a material remain parallel and maintain a constant distance while translating relative to each other. A “shear acoustic mode” is an acoustic vibration mode in a medium that results in shear deformation of the medium. The shear deformations in the XBAR 400 are represented by the curves 460, with the adjacent small arrows providing a schematic indication of the direction and magnitude of atomic motion. The degree of atomic motion, as well as the thickness of the piezoelectric plate 410, have been greatly exaggerated for ease of visualization. While the atomic motions are predominantly lateral (i.e. horizontal as shown in FIG. 4), the direction of acoustic energy flow of the excited primary shear acoustic mode is substantially orthogonal to the surface of the piezoelectric plate, as indicated by the arrow 465.

An acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. High piezoelectric coupling enables the design and implementation of microwave and millimeter-wave filters with appreciable bandwidth.

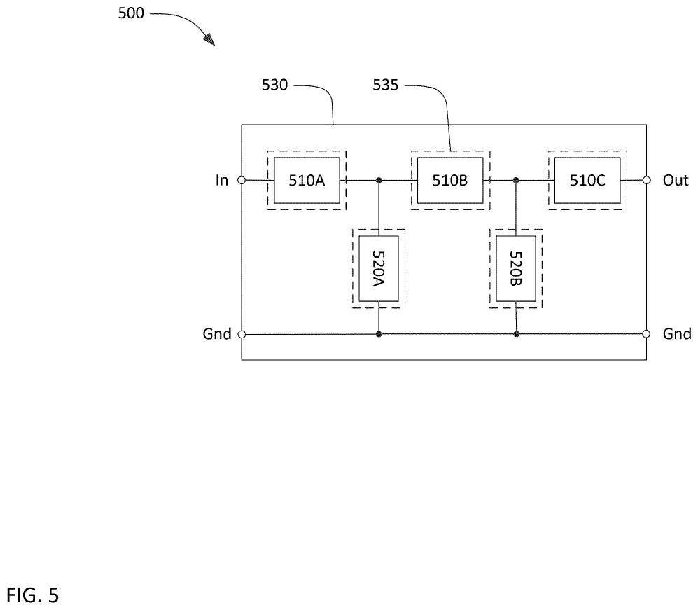

FIG. 5 is a schematic circuit diagram and layout for a high frequency band-pass filter 500 using XBARs. The filter 500 has a conventional ladder filter architecture including three series resonators 510A, 510B, 510C and two shunt resonators 520A, 520B. The three series resonators 510A, 510B, and 510C are connected in series between a first port and a second port (hence the term “series resonator”). In FIG. 5, the first and second ports are labeled “In” and “Out”, respectively. However, the filter 500 is bidirectional and either port may serve as the input or output of the filter. The two shunt resonators 520A, 520B are connected from nodes between the series resonators to ground. A filter may contain additional reactive components, such as inductors, not shown in FIG. 5. All the shunt resonators and series resonators are XBARs. The inclusion of three series and two shunt resonators is exemplary. A filter may have more or fewer than five total resonators, more or fewer than three series resonators, and more or fewer than two shunt resonators. Typically, all of the series resonators are connected in series between an input and an output of the filter. All of the shunt resonators are typically connected between ground and the input, the output, or a node between two series resonators.

In the exemplary filter 500, the three series resonators 510A, B, C and the two shunt resonators 520A, B of the filter 500 are formed on a single plate 530 of piezoelectric material bonded to a silicon substrate (not visible). Each resonator includes a respective IDT (not shown), with at least the fingers of the IDT disposed over a cavity in the substrate. In this and similar contexts, the term “respective” means “relating things each to each”, which is to say with a one-to-one correspondence. In FIG. 5, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 520A, 520B in the filter 500 has resonance where the admittance of the resonator is very high and an anti-resonance where the admittance of the resonator is very low. The resonance and anti-resonance occur at a resonance frequency and an anti-resonance frequency, respectively, which may be the same or different for the various resonators in the filter 500. In over-simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are position above the upper edge of the passband.

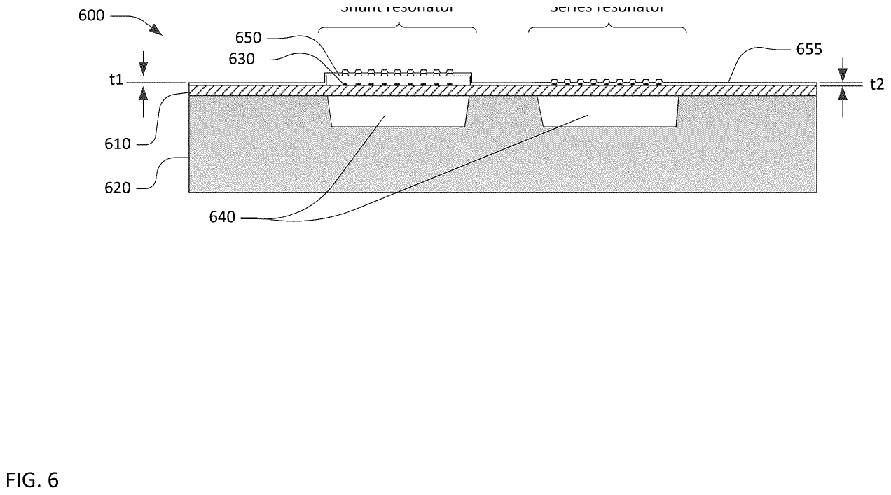

FIG. 6 is a schematic cross-sectional view through a shunt resonator and a series resonator of a filter 600 that uses a dielectric frequency setting layer to separate the resonance frequencies of shunt and series resonators. A piezoelectric plate 610 is attached to a substrate 620. Portions of the piezoelectric plate 610 form diaphragms spanning cavities 640 in the substrate 620. Interleaved IDT fingers, such as finger 630, are formed on the diaphragms. A first dielectric layer 650, having a thickness t1, is formed over the IDT of the shunt resonator. The first dielectric layer 650 is considered a “frequency setting layer”, which is a layer of dielectric material applied to a first subset of the resonators in a filter to offset the resonance frequencies of the first subset of resonators with respect to the resonance frequencies of resonators that do not receive the dielectric frequency setting layer. The dielectric frequency setting layer is commonly SiO₂ but may be silicon nitride, aluminum oxide, or some other dielectric material. The dielectric frequency setting layer may be a laminate or composite of two or more dielectric materials.

A second dielectric layer 655, having a thickness t2, may be deposited over both the shunt and series resonator. The second dielectric layer 655 serves to seal and passivate the surface of the filter 600. The second dielectric layer 655 may be the same material as the first dielectric layer or a different material. The second dielectric layer may be a laminate or composite of two or more different dielectric materials. Further, as will be described subsequently, the thickness of the second dielectric layer may be locally adjusted to fine-tune the frequency of the filter 600A. Thus, the second dielectric layer can be referred to as the “passivation and tuning layer”.

The resonance frequency of an XBAR is roughly proportional to the inverse of the total thickness of the diaphragm including the piezoelectric plate 610 and the dielectric layers 650, 655. The diaphragm of the shunt resonator is thicker than the diaphragm of the series resonator by the thickness t1 of the dielectric frequency setting layer 650. Thus, the shunt resonator will have a lower resonance frequency than the series resonator. The difference in resonance frequency between series and shunt resonators is determined by the thickness t1.

A potential problem in acoustic resonators on thin floating piezoelectric diaphragms is deformation of the diaphragm due to stress. Such stress may result in out-of-plane bowing of the diaphragm and/or periodic out-of-plane ripples in the diaphragm. Sources of stress include inherent tensile stress from some elements of the acoustic resonator such as IDT conductors and/or thermal expansion mismatch between the diaphragm and other elements including the substrate. Stress in the diaphragm may be relieved, at least partially, by having at least some portion of the perimeter of the cavity curved rather than straight.

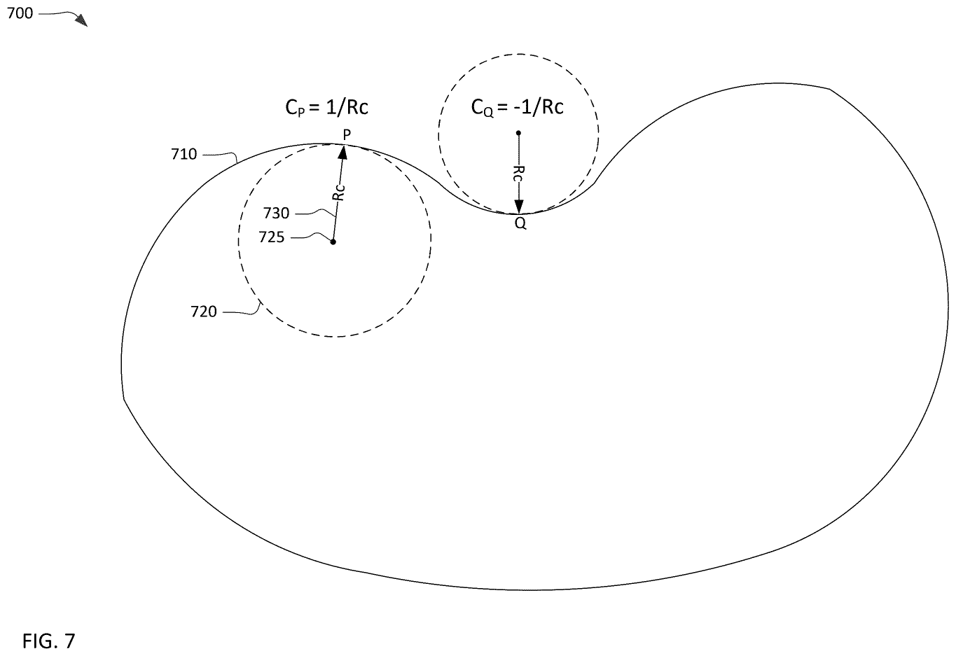

FIG. 7 is a graphic that illustrates the definition of the curvature of a line. The line 710 is a two-dimensional closed curved line having an arbitrary shape. The circle 720 is the so-called “osculating circle”, which is the circle that best approximates the curve 710 at a point P. More precisely, given a point P on the curve 710, every other point X (not shown) of the curve 710 defines a circle (or sometimes a line) passing through X and tangent to the curve at P. The osculating circle is the limit, if it exists, of this circle when X closely approaches P. Radial line 730 joins point P to the center 725 of the osculating circle 720. The length Rc of the radial line 730 is the “radius of curvature” of the curve 710 at the point P. The curvature Cp at the point P is the reciprocal of Rc. The curvature at a point on the perimeter of a cavity is positive if the radial line joining the point and the center of the corresponding osculating circle is within or crosses the cavity. For example, the curvature of the line 710 at point P is positive. Conversely, the curvature at a point on the perimeter of a cavity is negative if the radial line joining the point and the center of the corresponding osculating circle is outside of the cavity. For example, the curvature of the line 710 at point Q is negative.

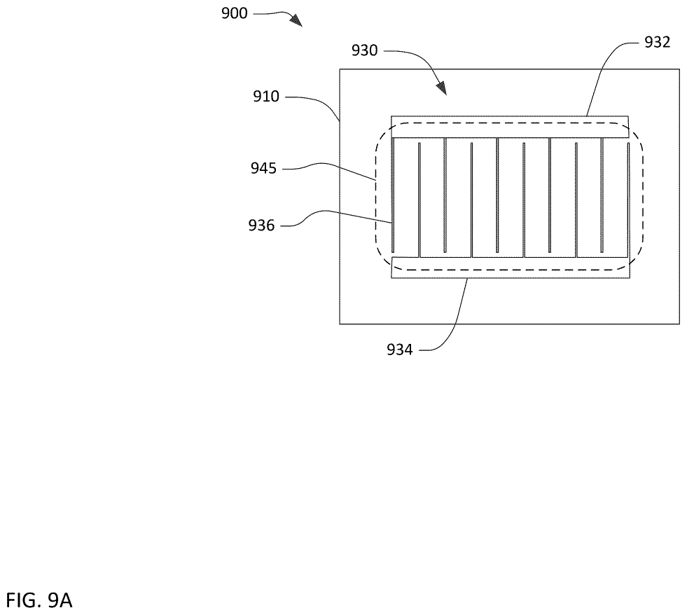

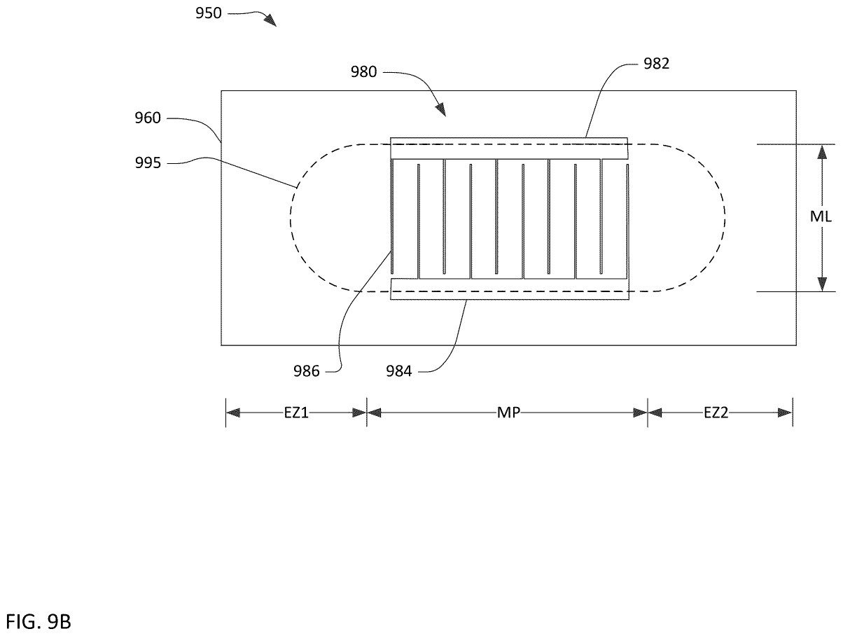

The curvature at a portion of the perimeter of a cavity is round if the radius of the portion is equal to the length of the radial line joining the portion and the center of the corresponding osculating circle. For example, end zones EZ1 and EZ2 of FIG. 9B may be two portions of the perimeter 995 of a cavity that are round. They may be rounded ends of the cavity having a radial line or radius that is half of a length ML off the middle portion MP of the perimeter. The rounded ends may be semicircles extending past the ends of middle portion MP.

Since the radius of curvature of a straight line is infinite, the curvature of a straight line is zero. Conversely, since the radius of a sharp corner (for example a corner formed by the intersection of two lines) is zero, the curvature of such a corner is infinite.

In this patent, the perimeter of a cavity is “curved” if the curvature for at least one point on the perimeter is non-zero and finite. The perimeter 145 of the cavity 140 in FIG. 1 is not curved. The curvature of the perimeter 145 is zero along the straight top, bottom, left, and right (as seen in the figure) sides of the cavity and infinite in the corners where the sides intersect. At no point on the perimeter 145 is the curvature both non-zero and finite. This will be true of any perimeter having only straight sides.

The perimeter of a cavity is “continuously curved” if the curvature is non-zero and finite at every point along the perimeter. For example, continuously curved may be when the curvature is either positive or negative at every point along the perimeter; and is not zero or infinity at any point along the perimeter. The perimeter of a cavity is “corner-less” if the curvature is finite at all points along the perimeter. For example, corner-less may be when the curvature crosses zero to go from positive to negative or vice versa; but is not infinity at any point along the perimeter.

A portion of the perimeter having positive curvature is “convex”, and a portion of the perimeter having negative curvature is “concave”. The perimeter of a cavity is continuously convex if the curvature at every point on the perimeter is finite and greater than zero. The perimeter of the cavity is “non-concave” if the curvature at every point on the perimeter is finite and greater than or equal to zero.

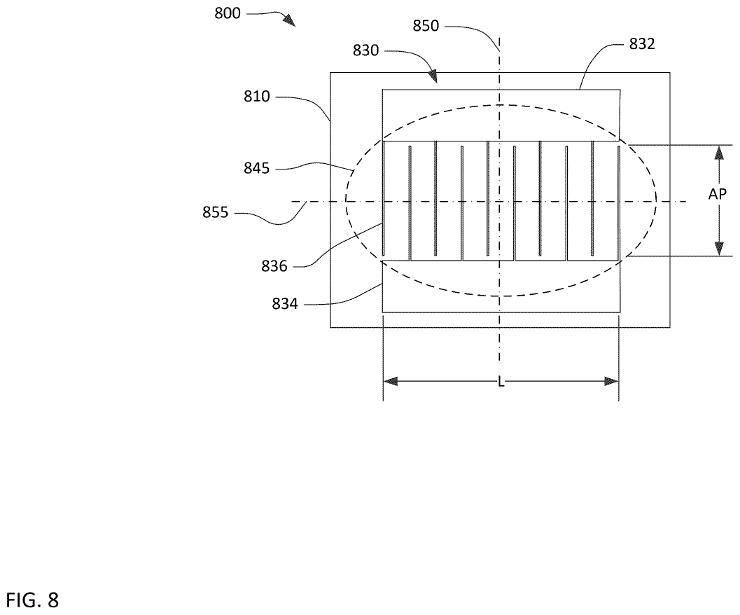

FIG. 8 is a schematic plan view of an exemplary XBAR 800 with a cavity having a curved perimeter. A piezoelectric plate 810 is attached to a substrate (not visible behind the piezoelectric plate 810) with a portion of the piezoelectric plate 810 forming a diaphragm spanning a cavity in the substrate. The dashed line is the perimeter 845 of the cavity defined by the intersection of the cavity and the surface of the substrate. The portion of the piezoelectric plate 810 within the dashed line is the diaphragm. An IDT 830 is formed on the surface of the piezoelectric plate facing away from the cavity. The IDT includes a first busbar 832, a second busbar 834, and a plurality of interleaved fingers, such as finger 836, disposed on the diaphragm.

In this example, the perimeter 845 of the cavity is an ellipse. An ellipse may be the best cavity perimeter shape for relieving stress in the diaphragm. However, an elliptical perimeter results in a substantial increase in both the diaphragm area and overall area of the XBAR device compared, for example, to the XBAR device 100 of FIG. 1 with a rectangular cavity perimeter 145. The elliptical perimeter 845 is continuously curved, corner-less, and non-concave as those terms were previously defined.

The perimeter 845 of the cavity of the XBAR 800 is symmetric about a first axis 850 which bisects the length L of the IDT. The perimeter 845 of the cavity of the XBAR 800 is also symmetric about a second axis 855 which bisects the aperture AP of the IDT. The perimeter 845 may be described as having two-axis symmetry.

FIG. 9A is a schematic plan view of another exemplary XBAR 900 with a cavity having a curved perimeter 945. A piezoelectric plate 910 is attached to a substrate (not visible) with a portion of the piezoelectric plate forming a diaphragm spanning a cavity in the substrate. The dashed line is the perimeter 945 of the cavity defined by the intersection of the cavity and the surface of the substrate. An IDT 930 is formed on the surface of the piezoelectric plate 910 facing away from the cavity. The IDT includes a first busbar 932, a second busbar 934, and a plurality of interleaved fingers such as finger 936.

The perimeter 945 of the cavity is generally a rectangle with rounded corners. The perimeter is curved, corner-less, and non-concave as those terms were previously defined. The perimeter 945 has two-axis symmetry.

FIG. 9B is a schematic plan view of another exemplary XBAR 950 with a cavity having a curved perimeter 995. A piezoelectric plate 960 is attached to a substrate (not visible behind the piezoelectric plate 960) with a portion of the piezoelectric plate 960 forming a diaphragm spanning a cavity in the substrate. The dashed line is the perimeter 995 of the cavity defined by the intersection of the cavity and the surface of the substrate. Perimeter 995 has a rectangular shaped middle portion MP and semicircular end zones EZ1 and EZ2. The portion of the piezoelectric plate 960 within the dashed line is the diaphragm. An IDT 980 is formed on the surface of the piezoelectric plate facing away from the cavity. The IDT includes a first busbar 982, a second busbar 984, and a plurality of interleaved fingers, such as finger 986, disposed on the diaphragm.

The perimeter 995 of the cavity is curved, corner-less, and non-concave as those terms were previously defined. The perimeter also has continuously curved and continuously convex ends or end zones. The perimeter 995 may be described as having two-axis symmetry. The perimeter 995 of the cavity of the XBAR 950 is symmetric about a first axis which bisects the length L of the IDT. The perimeter 955 of the cavity of the XBAR 950 is also symmetric about a second axis which bisects the aperture AP of the IDT.

The round end zones EZ1 and EZ2 have a length ML that is the same as a length ML off the middle portion MP of the perimeter so there are no corners where the end zones meet the middle portion. The end zones have a width (not numbered but roughly shown by EZ1 and EZ2) that is much less than a width (not numbered but roughly shown by MP) off the middle portion MP of the perimeter. These lengths are symmetric about a second axis which bisects the aperture AP of the IDT. In some cases, the lengths of the features in this figure are many times less than what is shown in the figure and the number of interleaved fingers is many times greater than that shown in the figure. In some cases, the width of the end zones is between 0.1 and 0.3 times the width of the middle portion. In some cases, the width of the end zones is between 0.12 and 0.17 times the width of the middle portion. In some cases, ML is between 40 and 100 micrometers (μm) and width of MP is between 250 and 500 μm. In some cases, ML is between 50 and 70 μm and width of MP is between 350 and 450 μm.

Perimeter 995 may have a curvature at portions that are EZ1 and EZ2 of the perimeter that are round or semicircular in shape, and portions that are MP of the perimeter that are straight or form a rectangle shape. In some cases, at least a portion of a perimeter 995 of the cavity is curved at EZ1 and EZ2; the perimeter of the cavity is corner-less; and the end zones EZ1 and EZ2 of the perimeter of the cavity are round. The perimeter 955 may be generally oval with horizontal sides that are straight and parallel. It may have a hot dog or two dimensional capsule shape.

In this example, the perimeter 995 results in a substantial increase in both the diaphragm area and overall area of the XBAR device compared, for example, to the XBAR device 100 of FIG. 1 with a rectangular cavity perimeter 145. This increase may not be desired because it results in fewer XBAR devices formed in the same amount of substrate area. Also, the increased diaphragm area may result in lower bandpass frequency.

However, the perimeter 995 of the cavity may be the best cavity perimeter shape for relieving stress in the diaphragm. Notably, the stress in the diaphragm may be concentrated at the ends of the diaphragm during non-operating conditions such as during fabrication annealing, and the stress may not change with the shape of the ends of the diaphragm and the ends of the IDT metal layer (e.g., these ends being where MP ends and the end zones EZ1 and EZ2 begin). For example, the shape of the length ML and of end zones EZ1 and EZ2 of the perimeter 995 do effect the amount of stress in the diaphragm. In some case, the stress is along the metal edges of the IDT (e.g., stress is where MP ends and the end zones EZ1 and EZ2 begin), and is concentrated at the junction area where metal edges are crossing the cavity and/or diaphragm edge (e.g., stress is concentrated where MP ends and the end zones EZ1 and EZ2 begin). However, the perimeter 995 of the cavity has no corners or bends at these junctions, thus relieving stress in the diaphragm during non-operating and operating conditions.

The perimeter 995 has some space in the end zones of the cavity to help reduce stress at the diaphragm ends by allowing the diaphragm ends to bend gradually to reduce stress at those ends. For the same busbar shape (e.g., a rounded shape not shown), a narrow membrane with round cavity ends as in XBAR 950 may result in the minimum stress in the diaphragm.

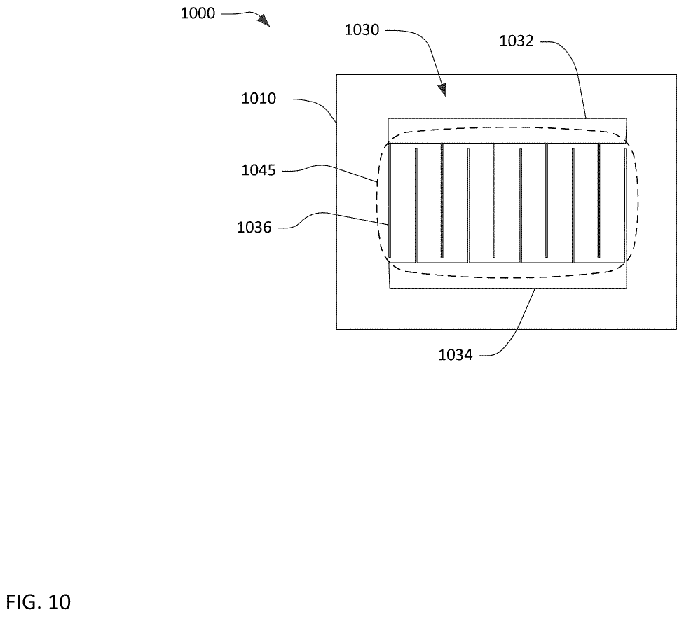

FIG. 10 is a schematic plan view of another exemplary XBAR 1000 with a cavity having a curved perimeter 1045. A piezoelectric plate 1010 is attached to a substrate (not visible) with a portion of the piezoelectric plate forming a diaphragm spanning a cavity in the substrate. The dashed line is the perimeter 1045 of the cavity defined by the intersection of the cavity and the surface of the substrate. An IDT 1030 is formed on the surface of the piezoelectric plate facing away from the cavity. The IDT includes a first busbar 1032, a second busbar 1034, and a plurality of interleaved fingers such as finger 1036.

The perimeter 1045 of the cavity is generally rectangular with rounded corners and curved edges. The perimeter is continuously curved, continuously convex, and corner-less as those terms were previously defined. The perimeter 1045 has two-axis symmetry.

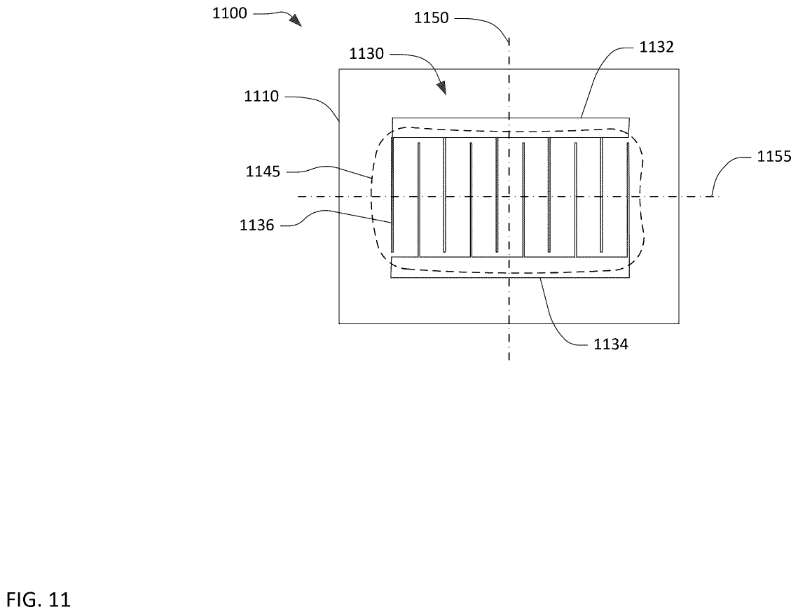

FIG. 11 is a schematic plan view of another exemplary XBAR 1100 with a cavity having a curved perimeter 1145. A piezoelectric plate 1110 is attached to a substrate (not visible) with a portion of the piezoelectric plate forming a diaphragm spanning a cavity in the substrate. The dashed line is the perimeter 1145 of the cavity defined by the intersection of the cavity and the surface of the substrate. An IDT 1130 is formed on the surface of the piezoelectric plate facing away from the cavity. The IDT includes a first busbar 1132, a second busbar 1134, and a plurality of interleaved fingers such as finger 1136.

The perimeter 1145 of the cavity is generally rectangular with rounded corners and curved edges. In contrast to the perimeter 1045 of FIG. 10, the upper and right edges (as seen in the figure) are concave. The perimeter 1145 is continuously curved, and corner-less but is not continuously convex, as those terms were previously defined. The perimeter 1045 is asymmetrical about both a first axis 1150 that bisects a length of the IDT and a second axis 1155 that bisects an aperture of the IDT.

The cavity perimeters 845, 945, 995, 1045, and 1145 shown in FIG. 8 through FIG. 11, respectively, are examples of the unlimited number of possible configurations of curved perimeters. At least a portion of a curved cavity perimeter is curved. The curved portion may be all or part of a single edge or a single rounded corner. The curved portion may encompass the entire perimeter. The curved portion may be convex or concave. The perimeter may be symmetrical about none, one, or both of a first axis that bisects a length of the IDT or a second axis that bisects an aperture of the IDT. At least a portion of a perimeter of the cavity may be curved and at least one end zone of the perimeter of the cavity may be round.

### Description of Methods

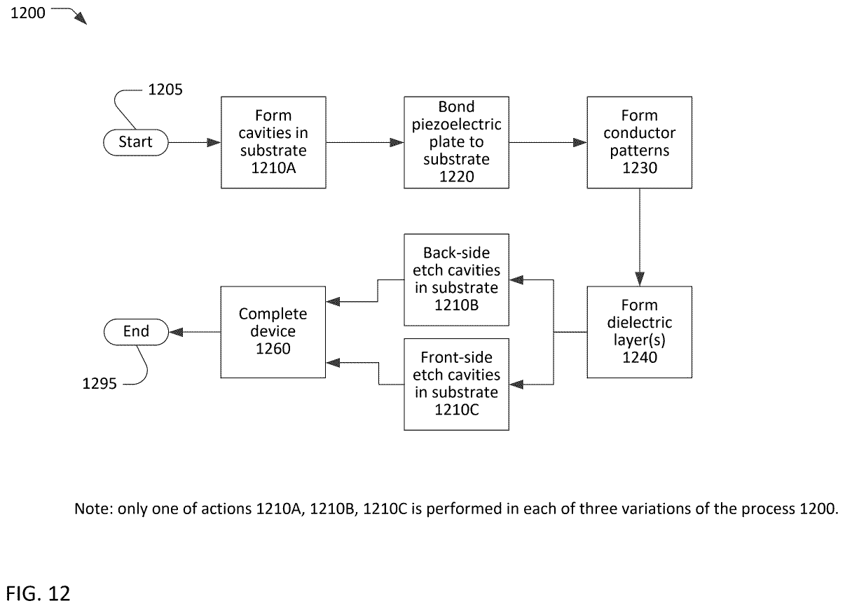

FIG. 12 is a simplified flow chart showing a process 1200 for making an XBAR or a filter incorporating XBARs. The process 1200 starts at 1205 with a substrate and a plate of piezoelectric material and ends at 1295 with a completed XBAR or filter. The flow chart of FIG. 12 includes only major process steps. Various conventional process steps (e.g. surface preparation, cleaning, inspection, baking, annealing, monitoring, testing, etc.) may be performed before, between, after, and during the steps shown in FIG. 12.

The flow chart of FIG. 12 captures three variations of the process 1200 for making an XBAR which differ in when and how cavities are formed in the substrate. The cavities may be formed at steps 1210A, 1210B, or 1210C. Only one of these steps is performed in each of the three variations of the process 1200.

The piezoelectric plate may be, for example, Z-cut lithium niobate or lithium tantalate as used in the previously presented examples. The piezoelectric plate may be some other material and/or some other cut. The substrate may preferably be silicon. The substrate may be some other material that allows formation of deep cavities by etching or other processing.

In one variation of the process 1200, one or more cavities are formed in the substrate at 1210A before the piezoelectric plate is bonded to the substrate at 1220. A separate cavity may be formed for each resonator in a filter device. The one or more cavities may be formed using conventional photolithographic and etching techniques. Typically, the cavities formed at 1210A will not penetrate through the substrate, and the resulting resonator devices will have a cross-section as shown in FIG. 3.

At 1220, the piezoelectric plate is bonded to the substrate. The piezoelectric plate and the substrate may be bonded by a wafer bonding process. Typically, the mating surfaces of the substrate and the piezoelectric plate are highly polished. One or more layers of intermediate materials, such as an oxide or metal, may be formed or deposited on the mating surface of one or both of the piezoelectric plate and the substrate. One or both mating surfaces may be activated using, for example, a plasma process. The mating surfaces may then be pressed together with considerable force to establish molecular bonds between the piezoelectric plate and the substrate or intermediate material layers.

A conductor pattern, including IDTs of each XBAR, is formed at 1230 by depositing and patterning one or more conductor layers on the front side of the piezoelectric plate. The conductor layer may be, for example, aluminum, an aluminum alloy, copper, a copper alloy, or some other conductive metal. Optionally, one or more layers of other materials may be disposed below (i.e. between the conductor layer and the piezoelectric plate) and/or on top of the conductor layer. For example, a thin film of titanium, chrome, or other metal may be used to improve the adhesion between the conductor layer and the piezoelectric plate. A conduction enhancement layer of gold, aluminum, copper or other higher conductivity metal may be formed over portions of the conductor pattern (for example the IDT bus bars and interconnections between the IDTs).

The conductor pattern may be formed at 1230 by depositing the conductor layer and, optionally, one or more other metal layers in sequence over the surface of the piezoelectric plate. The excess metal may then be removed by etching through patterned photoresist. The conductor layer can be etched, for example, by plasma etching, reactive ion etching, wet chemical etching, and other etching techniques.

Alternatively, the conductor pattern may be formed at 1230 using a lift-off process. Photoresist may be deposited over the piezoelectric plate. and patterned to define the conductor pattern. The conductor layer and, optionally, one or more other layers may be deposited in sequence over the surface of the piezoelectric plate. The photoresist may then be removed, which removes the excess material, leaving the conductor pattern.

At 1240, a front-side dielectric layer may be formed by depositing one or more layers of dielectric material on the front side of the piezoelectric plate. The one or more dielectric layers may be deposited using a conventional deposition technique such as sputtering, evaporation, or chemical vapor deposition. The one or more dielectric layers may be deposited over the entire surface of the piezoelectric plate, including on top of the conductor pattern. Alternatively, one or more lithography processes (using photomasks) may be used to limit the deposition of the dielectric layers to selected areas of the piezoelectric plate, such as only between the interleaved fingers of the IDTs. Masks may also be used to allow deposition of different frequency setting dielectric layers on different portions of the piezoelectric plate.

In a second variation of the process 1200, one or more cavities are formed in the back side of the substrate at 1210B. A separate cavity may be formed for each resonator in a filter device. The one or more cavities may be formed using an anisotropic or orientation-dependent dry or wet etch to open holes through the back side of the substrate to the piezoelectric plate. In this case, the resulting resonator devices will have a cross-section as shown in FIG. 1.

In a third variation of the process 1200, one or more cavities in the form of recesses in the substrate may be formed at 1210C by etching the substrate using an etchant introduced through openings in the piezoelectric plate. A separate cavity may be formed for each resonator in a filter device. The one or more cavities formed at 1210C will not penetrate through the substrate, and the resulting resonator devices will have a cross-section as shown in FIG. 3.

In all variations of the process 1200, the filter device is completed at 1260. Actions that may occur at 1260 include depositing a passivation and tuning layer such as SiO₂ or Si₃O₄ over all or a portion of the device; forming bonding pads or solder bumps or other means for making connection between the device and external circuitry; excising individual devices from a wafer containing multiple devices; other packaging steps; and testing. Any dielectric layer deposited at 1260 or elsewhere in the process 1200 is deposited over all resonators. Another action that may occur at 1260 is to tune the resonant frequencies of the resonators within the device by adding or removing metal or dielectric material from the front side of the device. After the filter device is completed, the process ends at 1295.

### Closing Comments

Throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. An acoustic resonator device comprising:
a substrate;
a piezoelectric layer attached to the substrate, wherein at least a portion of the piezoelectric layer is disposed over a cavity of the acoustic resonator device; and
an interdigital transducer (IDT) on a surface of the piezoelectric layer, the IDT including interleaved fingers extending at least over the portion of the piezoelectric layer disposed over the cavity,
wherein the cavity has at least one rounded corner, and
wherein a portion of interleaved fingers extend from at least one busbar,
wherein at least a portion of the rounded corner of the cavity is under the at least one busbar in a plan view of the piezoelectric layer.

2. The acoustic resonator device of claim 1, wherein the piezoelectric layer and the IDT are configured such that a radio frequency signal applied to the IDT excites a primary shear acoustic mode in the piezoelectric layer, the primary shear acoustic mode being a bulk shear mode where acoustic energy propagates along a direction substantially orthogonal to the surface of the piezoelectric layer, which is also transverse to a direction of an electric field created by the interleaved fingers.

3. The acoustic resonator device of claim 1, wherein the perimeter of the cavity is disposed at an intersection of the cavity and a surface of the substrate.

4. The acoustic resonator device of claim 1,
wherein the cavity comprises a pair of end zones that each have a length that is equal to a length of a middle portion of the perimeter and that each have a width that is less than a width of the middle portion of the perimeter, and
wherein the pair of end zones are semicircular and the width of the end zones is between 0.1 and 0.3 times the width of the middle portion.

5. The acoustic resonator device of claim 1, wherein the perimeter of the cavity is a rectangle having four rounded corners that includes the at least one rounded corner.

6. The acoustic resonator device of claim 1, wherein the substrate comprises a combination of materials.

7. The acoustic resonator device of claim 1, wherein the piezoelectric layer is attached to the substrate either directly or via one or more intermediate layers.

8. The acoustic resonator device of claim 1, wherein the cavity includes a side that defines a perimeter of the cavity in the plan view of the surface of the piezoelectric layer, and the at least one rounded corner includes the four rounded corners.

9. The acoustic resonator device of claim 1, wherein the at least one busbar overlaps at least the portion of the at least one rounded corner of the cavity in a thickness direction of the piezoelectric layer.

10. The acoustic resonator device of claim 1, wherein the at least one busbar overlaps at least the portion of the least one rounded corner of the cavity.

11. An acoustic resonator device comprising:
a piezoelectric layer including a portion that forms a diaphragm over a cavity of the acoustic resonator device; and
an interdigital transducer (IDT) on a surface of the piezoelectric layer, the IDT including interleaved fingers that extend from a pair of busbars,
wherein the interleaved fingers of the IDT are over at least a portion of the piezoelectric layer that forms a diaphragm over a cavity of the acoustic resonator device,
wherein the cavity includes a perimeter defined in a plan view of the piezoelectric layer, and the diaphragm is the portion of the piezoelectric layer that is within the perimeter of the cavity, and
wherein the perimeter of the cavity includes at least one rounded corner that has a portion that overlaps the at least one busbar of the pair of busbars in the plan view of the piezoelectric layer.

12. The acoustic resonator device of claim 11, further comprising:
a substrate that comprises a combination of materials and that is attached to the piezoelectric layer either directly or via one or more intermediate layers,
wherein the perimeter of the cavity is disposed at an intersection of the cavity and a surface of the substrate.

13. The acoustic resonator device of claim 11, wherein the piezoelectric layer and the IDT are configured such that a radio frequency signal applied to the IDT excites a primary shear acoustic mode in the piezoelectric layer, the primary shear acoustic mode being a bulk shear mode where acoustic energy propagates along a direction substantially orthogonal to the surface of the piezoelectric layer, which is also transverse to a direction of an electric field created by the interleaved fingers.

14. The acoustic resonator device of claim 11,
wherein the cavity comprises a pair of end zones that each have a length that is equal to a length of a middle portion of the perimeter and that each have a width that is less than a width of the middle portion of the perimeter, and
wherein the pair of end zones are semicircular and the width of the end zones is between 0.1 and 0.3 times the width of the middle portion.

15. The acoustic resonator device of claim 11, wherein the perimeter of the cavity is a rectangle having four rounded corners that includes the at least one rounded corner.

16. The acoustic resonator device of claim 11, wherein the cavity includes a side that defines a perimeter of the cavity in the plan view of the surface of the piezoelectric layer, and the at least one rounded corner includes the four rounded corners.

17. The acoustic resonator device of claim 11, wherein the at least one busbar overlaps at least the portion of the at least one rounded corner of the perimeter of the cavity in a thickness direction of the piezoelectric layer.

18. A filter device, comprising:
a plurality of bulk acoustic resonators, with at least one of the bulk acoustic resonators including:
a substrate;
a piezoelectric layer attached to the substrate, wherein at least a portion of the piezoelectric layer is disposed over a cavity of the acoustic resonator device; and
an interdigital transducer (IDT) on a surface of the piezoelectric layer, the IDT including interleaved fingers extending at least over the portion of the piezoelectric layer disposed over the cavity,
wherein the cavity has at least one rounded corner, and
wherein a portion of interleaved fingers extend from at least one busbar,
wherein at least a portion of the rounded corner of the cavity is under the at least one busbar in a plan view of the piezoelectric layer.

19. The filter device of claim 18, wherein the piezoelectric layer and the IDT of the at least one bulk acoustic resonator are configured such that a radio frequency signal applied to the IDT excites a primary shear acoustic mode in the piezoelectric layer, the primary shear acoustic mode being a bulk shear mode where acoustic energy propagates along a direction substantially orthogonal to the surface of the piezoelectric layer, which is also transverse to a direction of an electric field created by the interleaved fingers.

20. The filter device of claim 19, wherein the at least one busbar overlaps at least the portion of the at least one rounded corner of the cavity in a thickness direction of the piezoelectric layer.
